(19) United States
(12) Patent Application Publication
(10) Pub. No.: US 2026/0203474 A1
(43) Pub. Date: Jul. 16, 2026

(54) PREDICTING FOREST REGENERATION AFTER A DISTURBANCE

(71) Applicant: LANDYIELD HOLDINGS LLC, Houston, TX (US)

(72) Inventors: Mauricio Zapata-Cuartas, Yulee, FL (US); Jordan Golinkoff, Oakland, CA (US); Wu Ma, Suwanee, GA (US)

(21) Appl. No.: 19/020,428

(22) Filed: Jan. 14, 2025

(51) Int. Cl. G06F 30/27

(52) U.S. Cl. CPC G06F 30/27

(57) ABSTRACT

A method of estimating forest regeneration after a disturbance is disclosed. The method includes accessing a first model trained to predict a proportion of saplings in a forest after a disturbance, accessing a second model trained to predict a distribution of sapling species in a forest after a disturbance, and iteratively executing a growth and yield model to simulate growth of a stand. For at least one iteration, the method includes (i) retrieving information about the stand, (ii) applying the first model to the retrieved information to estimate the proportion of saplings in the stand (iii) applying the second model to the retrieved information to estimate the distribution of sapling species in the stand, and (iv) adjusting the stand information based on the estimated proportion of saplings and/or distribution of sapling species. The method further includes receiving, from the growth and yield model, a final report on the stand.

### BACKGROUND

Forest regeneration after a disturbance, such as a fire, impacts the commercial and ecological forest condition. However, accurate predictions of regeneration have proved difficult to achieve. The processes involved in regeneration are complex, and the modeling requirements vary widely. Existing process-based models and empirical models have very limited scope and are not generally adaptable to different regions and forest types (e.g., large spatial scales where multiple silvicultural management practices are required).

Natural forest regeneration is the initial biological response after a disturbance. The quality (species distribution) and quantity (number of seedlings) of regeneration present in the forest are influenced by the forest's ecological memory, which includes the adaptations, individuals, and materials that remain after a disturbance and support the forest's resilience to the disturbance. The ability of a forest site to naturally regenerate is affected by the characteristics and severity of the disturbance that it experiences. The type of disturbance can also influence the pattern of regrowth that occurs afterwards. For example, species-agnostic events (such as droughts, clear-cutting, or fires) can lead to different outcomes than species-specific disturbances, like those caused by pathogens or insects that target particular species or silviculture that harvests only certain high-value species.

This document describes methods and systems that address issues such as those discussed above, and/or other issues.

### SUMMARY

The present disclosure describes embodiments related to predicting forest regeneration after a disturbance. A method of predicting forest regeneration after a disturbance includes accessing a first model trained to predict a proportion of saplings relative to more mature trees in a forest after a disturbance, accessing a second model trained to predict a distribution of sapling species in a forest after a disturbance, and iteratively executing a forest growth and yield model to simulate growth of a stand of a forest. For at least one iteration, the method includes (i) retrieving (from the forest growth and yield model) information about the stand, (ii) applying the first model to the retrieved stand information to estimate the proportion of saplings in the stand, (iii) applying the second model to the retrieved stand information to estimate the distribution of sapling species in the stand, and (iv) adjusting the stand information of the forest growth and yield model based on the estimated proportion of saplings and/or the estimated distribution of sapling species. The method further includes receiving, from the forest growth and yield model, a final report on the stand.

Implementations of the disclosure may include one or more of the following optional features. In some examples, the method further includes training the first model to predict the proportion of saplings in a forest after a disturbance, the proportion of saplings including a ratio of a number of saplings to a total number of trees per acre (TPA) in the stand. Training the first model may include training a Random Forest (RF) model. Training the RF model may include accessing information including sapling counts by species for each of multiple plots of a forest; and training the RF model on at least a portion of the accessed information. Training the RF model may further include preprocessing the information to exclude plots having less than a threshold number of saplings before training the RF model. In some examples, the method further includes training the second model to predict the distribution of sapling species in a forest after a disturbance. Training the second model may include training an Artificial Neural Network (ANN) model. Training the ANN model may include training a deep neural network (DNN) having at least one layer that includes a softmax activation function. Training the ANN model may include training a DNN network having at least inner layers that each includes a sigmoid activation function.

In some examples, iteratively executing the forest growth and yield model to simulate growth of the stand of a forest includes executing the forest growth and yield model to iterate over multiple time periods. After applying the second model to the retrieved stand information, the method may further include applying one or more constraints or adjustments to an output of the first model and/or the second model. Applying the one or more constraints or adjustments may include reducing the estimated number of saplings based on a proportion of a basal area of a sapling species in the overstory. The method may further include, after completing all iterations, outputting the final report regarding the stand. The method may further include, before applying the first model to the retrieved stand information, validating the first model based on a k-fold-cross-validation.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 shows a flowchart for an example process of combining a forest growth simulator with additional models.

FIG. 2 shows bar graphs of estimated forest growth.

FIG. 3 shows line graphs of estimated forest growth.

FIG. 4 shows an example Landsat analysis ready data tile showing the mid-Atlantic US as a grey scale image composite of bands X, Y, and Z.

FIG. 5 shows forested subregions.

FIG. 6 illustrates a block diagram of internal hardware included in any of the electronic components of this disclosure.

### DETAILED DESCRIPTION

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” (or “comprises”) means “including (or includes), but not limited to.” When used in this document, the term “exemplary” is intended to mean “by way of example” and is not intended to indicate that a particular exemplary item is preferred or required.

In this document, when terms such “first” and “second” are used to modify a noun or phrase, such use is simply intended to distinguish one item from another and is not intended to require a sequential order unless specifically stated. The term “about” when used in connection with a numeric value, is intended to include values that are close to, but not exactly, the number. For example, in some embodiments, the term “about” may include values that are within +/−10 percent of the value.

The present disclosure relates generally to methods and systems for predicting forest regeneration after a disturbance. In particular, the disclosed methods and systems combine different models with a forest growth simulator to produce an improved predictor of forest conditions after a disturbance. The resulting ensemble model more accurately simulates, e.g., post-disturbance timber availability, biomass development, etc. over time, particularly at the stand scale.

Silviculture is the science and practice of controlling the establishment, composition, structure and growth of forests and woodlands, e.g., to meet certain needs. A forest stand is a distinct management unit of a forest. In some examples, stands range in size from a few acres to several hundred acres. Trees within a stand may share certain characteristics, e.g., species, age, size, arrangement, condition, location, or any combination of these characteristics. In this document, tree recruitment is defined as the number of trees or saplings that grow to a specific measurement threshold over a given time interval. The threshold may include tree height (e.g., 1.3 m), and/or diameter (e.g., 5 cm at 4.5 feet above the ground, also known as Diameter at Breast Height, or DBH). The term sapling generally refers to a young tree that has passed the seedling phase. In some examples, a tree may be considered a sapling after reaching an age of four years and/or a height of three feet. Canopy-projected cover (or crown-projected cover), known as CPC, is the proportion of ground area covered by tree crowns. CPC is estimated by vertically projecting outlines of tree crowns onto the horizontal plane that represents the forest stand area. Forest canopy closure is when virtually the entire land surface is covered by tree canopies. The basal area of a sapling is the cross-sectional area of the tree's trunk at breast height. It may be a measurement of tree density in a given area of land.

A Random Forest (RF), also known as a random decision forest, is an ensemble-learning method for classification, regression and other tasks. RF models work by creating multiple distinct decision trees during training. For classification tasks, the output of the random forest model may be the most popular class/label, e.g., the class/label that is selected by the greatest number of trees. For regression tasks, the output may be the average of the predictions of the trees. By combining the outputs of separate decision trees, RF models correct for overfitting individual trees to their training data.

Artificial neural networks (ANNs) may be used for various tasks, including predictive modeling, adaptive control, and solving problems in artificial intelligence. They can learn from experience and can derive conclusions from a complex and seemingly unrelated set of information. ANNs include connected units or nodes, which loosely model the neurons in the brain. These nodes (known as artificial neurons) are connected by edges, which model synapses in the brain. Each artificial neuron receives signals from connected neurons, processes them, and sends a signal to other connected neurons. The output of each neuron is computed by some non-linear function of the sum of its inputs, known as the activation function. The strength of the signal at each connection is determined by a weight, which is adjusted during the learning process. Typically, neurons are aggregated into layers. Different layers may perform different transformations on their inputs. Signals travel from a first layer (e.g., the input layer) to the last layer (e.g., the output layer), possibly passing through multiple intermediate layers (e.g., hidden layers). A network is typically called a deep neural network (DNN) if it includes at least two hidden layers.

R is a programming language for statistical computing and data visualization. The core R language is augmented by a large number of extension packages, containing reusable code, documentation, and sample data. R Packages include a “randomForest” package and the “caret” (Classification And REgression Training) package, which contains functions to streamline the model training process for complex regression and classification problems. TensorFlow is an open-source library for numerical computation, large-scale machine learning, deep learning, and other statistical and predictive analytics workloads. TensorFlow can train and run deep neural networks. Keras provides a user-friendly high-level Application Programming Interface (API) that provides access to TensorFlow and simplifies the process of building and training deep neural networks. Both Keras and TensorFlow are accessible from the R programming environment.

As an interpreted language, R has a native command line interface. Thus, the R command line provides for rapid prototyping of data mining, statistic analysis, data visualization and other applications.

The response of forest regeneration to complex interactions between biotic and abiotic conditions and resource availability is still not fully understood. However, accurate forest growth simulation may be achieved by employing machine learning models to predict regeneration density, species composition, and recruitment, and incorporate these multiple models into a forest growth simulator, such as the Forest Vegetation Simulator (FVS) provided by the U.S. Forestry Service. FVS is an empirical forest growth model based on the Forest Inventory and Analysis (FIA) plots. It models individual tree growth as a function of average stand characteristics. FVS uses current forest inventory data to describe initial stand conditions and requires a description of the inventory design, stand attributes, and a list of individual tree information. Initial conditions are input using keywords and associated values.

FVS prediction system has three main sub-models: a Small Tree Model (STM), a Large Tree Model (LTM), and a Mortality Model. FVS uses a specific diameter as a breakpoint to differentiate between the small and large tree growth functions. The input data is primarily collected through field inventory on nested plot designs where larger trees are measured on the outer plot area and smaller trees are surveyed on an inner plot. Although the STM behaves differently from the LTM, its results are adjusted to produce a smooth, continuous growth form. The FVS model predicts forest growth for different geographic regions called variants, each of which has its own set of prediction equations. Several of these variants have an associated Full Regeneration Establishment Model Extension (FREM) that predicts understory tree development. Other variants include a Partial Regeneration Establishment Model (PREM), which lacks certain features of the FREM. FVS can be modified to run in the R environment, allowing access to deep neural networks (e.g., via Keras/TensorFlow) and Random Forest models (e.g., via “caret”), among others.

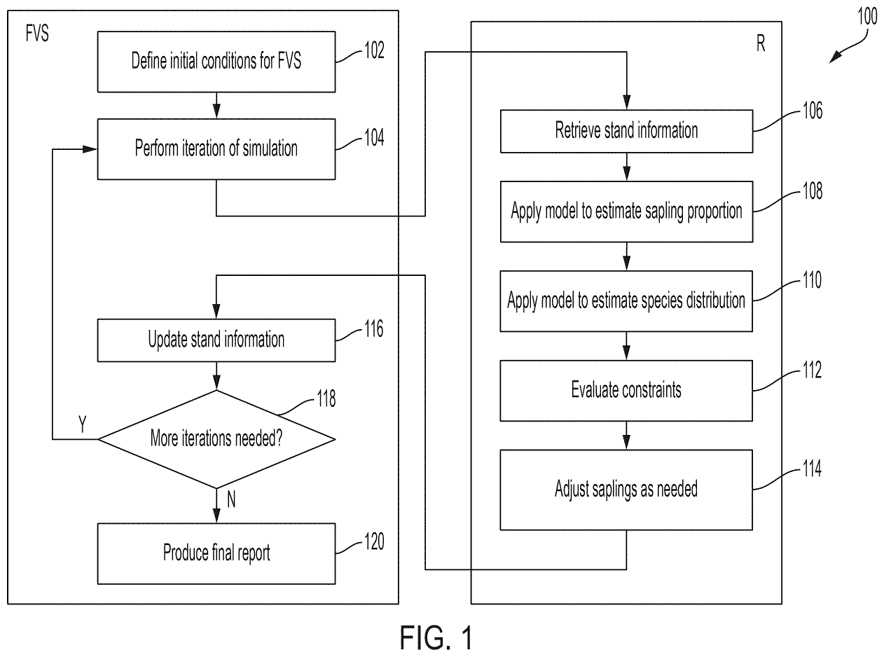

FIG. 1 shows a flowchart 100 for an example process of combining a forest growth simulator (FVS) with additional models to provide an enhanced model for predicting forest regeneration after a disturbance. FVS offers various cycle stop-point/restart options, enabling users to modify parameters in the middle of an FVS run. For example, the built-in FVS keyword “BeforeEstab” stops FVS before the establishment of regeneration following changes made due to harvest or other disturbances that would trigger regeneration. . . . Furthermore, FVS can be modified to run in the R programming environment. The example method uses this feature advantageously. That is, an executable version of FVS is run in the R environment and is configured to pause at particular, predefined points in the simulation and pass control back to the R environment, where the additional models may be used to adjust FVS parameters prior to restarting the simulation.

It should be noted that the R environment is only one approach to integrating combining a forest growth simulator (FVS) with additional models. Other interactive and/or scripting environments with interfaces to models may also be used. For example, command-line interpreters such as a UNIX/Linux shell, Tcl, and/or Python may also be used. In any of these environments (and others), FVS may be configured to stop at natural “stop points” and pass control back to the command interpreter. The command interpreter then processes additional commands, including accessing additional models (e.g., machine-learning models) and/or FVS files and parameters. Thus, the command interpreter orchestrates the interaction between FVS and, e.g., machine-learning models), resulting in the enhanced model for predicting forest regeneration after a disturbance.

In the example process, the overall prediction results from the ensemble of two ML model predictions coupled with the FVS simulations. In each cycle, the proportion of saplings is predicted based on overstory stand conditions. The species proportion of saplings is then predicted to allocate the new small trees at the species level.

At step 102, the process includes defining the initial conditions for the simulation. This step 102 may include using FVS keywords to define aspects of the stand being simulated and/or trees within the stand. FVS keywords may define, among other aspects, stand size, the breakpoint between small and large tree models, the number of distinct plots within the stand, and so forth. Other FVS keywords may affect the aspects of the simulation, such as stand growth and mortality, factors related to stand management, and so forth. FVS keywords may also direct FVS to read initialization files which may include additional keywords and definitions.

At step 104, the process includes performing one iteration of the simulation. For example, the iteration may be for a period of time, where the entire simulation includes multiple periods of time. The iteration may include modeling management activities associated with the stand. Stand management activities are often contingent upon several factors. Thinning may be called for if the stand is too dense. Usually, users of stand-growth simulation models must specify the occurrence of stand conditions that trigger management actions and then define the program options that represent those actions. In an example, silviculture can be defined to apply to a stand that may be configured to include a management policy of thinning the stand to a residual density of 300 trees per acre when the before-thinning crown competition factor (BCCF) is greater than 150, the before-thinning trees per acre (BTPA) is greater than 500, and the stand age is greater than 20 and less than 60. Other management policies are also within the scope of this disclosure. The iteration may also include simulating stand growth and stand mortality, e.g., based on the initial conditions for the stand. Finally, the iteration may include determining the crown-projected cover or other measure of the canopy of the stand. At step 106, the process includes, after performing an iteration of the simulation, retrieving information about the stand from FVS. The information may include the tree list, stand summary, and/or other FVS cycle variables at the end of the iteration. As shown in FIG. 1, after an iteration of the FVS simulation completes (e.g., when a predefined stop point that represents the end of an iteration is reached), control passes to the R environment. The stand information retrieved at step 106 may be stored in files or variables or otherwise be available to software running in the R environment, including trained AI models.

At step 108, the process includes applying a model to the retrieved information to predict the proportion of saplings in a stand after a disturbance. In some examples, the proportion of saplings for the stand is estimated using a calibrated Random Forest (RF) Machine Learning (ML) model using the variables and stand condition retrieved from FVS after each iteration. The U.S. Forest Inventory and Analysis (FIA) program data provided by the USDA Forest Service may be used to train and/or calibrate ML models. This data source provides information regarding the status of forests at regional and national scales. Moreover, the individual plot measurements provide a snapshot of forest conditions and incorporate detailed regeneration information at the time of plot measurement. Its sampling design has an intensity of one plot per approximately 6000 acres, producing a quasi-systematic random sample with nationally consistent measurements. In each plot, there is a sapling species proportion distribution that consists of a vector with a fixed length equal to the total number of unique sapling species observed in the sample. The vector contains values larger than zero for the species present in the plot and zeros for the non-observed species. Moreover, the sum of the values in the vector adds up to one. That is, step 108 may also include configuring and/or training the model as well as applying the model to the stand data.

In one embodiment, the proportion-of-saplings model is trained using preprocessed FIA plot attributes on a per-acre basis. That is, a matrix of sapling counts by species is created, where each row represents a plot, and the columns represent the species (e.g., using FVS species codes) present in the study area. To prepare the data for training, plots that lack age information are excluded, as well as forest types have only one plot. Finally, the data is filtered to plots having a non-zero (or at least a threshold) number of saplings. Parameters of the RF model (e.g., the number of decision trees and the number of randomly selected explanatory variables in each data subset) may be tuned using the “caret” package.

In another embodiment, the RF model is replaced by a parametric approach using a generalized linear mixed-effects model (GLMM) that includes a logit transformation, such as the “glmer” function in the “Ime4” R package. The expected proportion of saplings under the GLMM framework for a plot may be defined by the following equation, where Xᵢ₁, . . . . Xᵢₖ represent k stand predictor variables and potential interactions, and g is a grouping variable that is assuming different random effects in the model response for each grouping level. The grouping levels may be geographic areas or the sampled plot.

$$E ( {PS}_{i} ) = \frac{{e}^{( {β}_{0} + {β}_{1} {X}_{i 1} + {…β}_{k} {X}_{ik} \vert g )}}{1 + {e}^{( {β}_{0} + {β}_{1} {X}_{i 1} + {…β}_{k} {X}_{ki} \vert g )}}$$

Regardless of the model used to predict the proportion of saplings in the stand, the resulting Proportion of Saplings (PS) is the ratio of the number of saplings to the total trees per acre (TPA) in the stand (or each plot in the stand). Therefore, this ratio is always bounded between 0 and 1 (0 and 100%).

At step 110, the process includes applying a model to the retrieved information to estimate the distribution of sapling species in the stand. For example, the process may use a Machine Learning (ML) Artificial Neural Network (ANN) model, such as a Deep Neural Network (DNN), to predict the distribution of sapling species based on stand attributes retrieved from FVS. The example DNN model may include an initial normalized layer for the input data and may include a number of internal layers, each including a sigmoid activation function. The number of internal layers may be based on cross-validation criteria, such as a k-fold-cross-validation of the model (discussed in more detail below). The model may include a final layer that includes a softmax activation function so that the predicted proportions of each sapling species sum to one.

The DNN model may be based on the TensorFlow library. In some examples, the DNN is configured and trained using Keras. The input layer may normalize the input data, e.g., by shifting and/or scaling the input data into a distribution centered around 0 with a standard deviation of 1. The final layer (using the softmax activation function) converts the vector of values from the inner layers of the DNN model into a vector of a probability distribution, such that the output is in the range from 0 to 1 and sums up to 1. That is, the softmax output may be interpreted as a probability distribution over the possible species classes in the site area.

In another embodiment, the DNN model is replaced by a model based on multivariate regression analysis in which the dependent variable is treated as a composition of vectors with dependence, and the composition is analyzed by traditional regression analysis using log ratio transformations. A compositional data analysis program, such as the R package “compositional” may be used to fit this kind of statistical model to species proportion distribution of the FIA data. That is, step 110 may also include configuring and/or training the model as well as applying the model to the stand data.

Regardless of the model used to estimate the distribution of sapling species or to predict the proportion of saplings in the stand, the model may be validated, e.g., based on a k-fold-cross-validation. For each model, the variance explained (VE) based on cross-validation, the residual mean (aka—the error-E), and the root mean square difference or error (RMSE) may be computed as performance metrics, where Sⱼ is the observed value of the response variable being modeled, Si is the estimated value for the variable, and n is the total number of cases in the test sample. If the evaluation is on a single estimator per plot, the j subindex may take values of the sequence 1, 2, . . . , n, where n is the number of plots. Otherwise, the j subindex could be for n predictors within a plot, in which case each plot will have a V E, Ē and RMSE.

$$VE = ( 1 - \frac{{\sum }_{j = 1} {( {S}_{j} - {\hat{S}}_{j} )}^{2}}{{\sum }_{j = 1} {( {S}_{j} - {\overline{S}}_{j} )}^{2}} ) * 100$$

$$\overline{E} = \frac{{\sum }_{j = 1} ( {S}_{j} - {\hat{S}}_{j} )}{n}$$

$$RMSE = \sqrt{\frac{{\sum }_{j = 1} {( {S}_{j} - {\hat{S}}_{j} )}^{2}}{n}}$$

At step 112, the process may include applying one or more constraints or adjustments to the output of the models. For example, depending on the size of the existing species distribution of overstory trees, the number of saplings predicted/estimated by the models may be reduced. In some examples, if the overstory proportion of a given species is between 2 and 5% of the total overstory, the number of saplings of that species may be reduced by 20%. Alternatively, if the overstory proportion of a given species is greater than 5% of the total overstory, the number of saplings may be increased by 60%. After adjusting the species proportions, these proportions may be recalculated so that they continue to sum up to one.

At step 114, the process includes adjusting, if needed, parameters of the simulation based on the predicted proportion of saplings in a stand and the estimated distribution of sapling species. The simulation may include an associated tree list that enumerates all trees in the stand. Step 112 may include adjusting the saplings of the tree list based on the outputs of the models. For example, the total estimated number of new saplings may be computed by multiplying the proportion of saplings by the stand TPA in the iteration. If the predicted proportion of saplings in a stand and the estimated distribution of sapling species indicate that there should be more saplings in the stand than are included in the tree list retrieved from FVS, step 112 may include adding more saplings to be consistent with the model outputs. The added saplings may be given default attributes. For example, all new saplings included in the tree list may be assigned a default diameter of 2.5 in, a height of 12 ft and a crown ratio of 50.

After step 114, the updated simulation state information is reloaded to FVS. At step 116, after the updated simulation state information has been reloaded in FVS, the simulation is permitted to continue at step 118, i.e., to run for another iteration as described above or, if there are no more iterations to run, to complete the simulation.

At step 120, the process includes producing a final report regarding the stand. The report may include predicted tree volumes, biomass, density, canopy cover, harvest yields, and more. In some examples, the final report includes data in tabular form. The data may include species, trees per acre, and average height of any regeneration occurring in the stand throughout the simulation. The final report may also include statistical data including volumes, trees per acre, and basal area for each species in the stand. The mean, standard deviation, coefficient of variation, and confidence limits across sample plots are also included for stand totals of these volume and density measures. The final report may be stored in one or more files and/or displayed to a user.

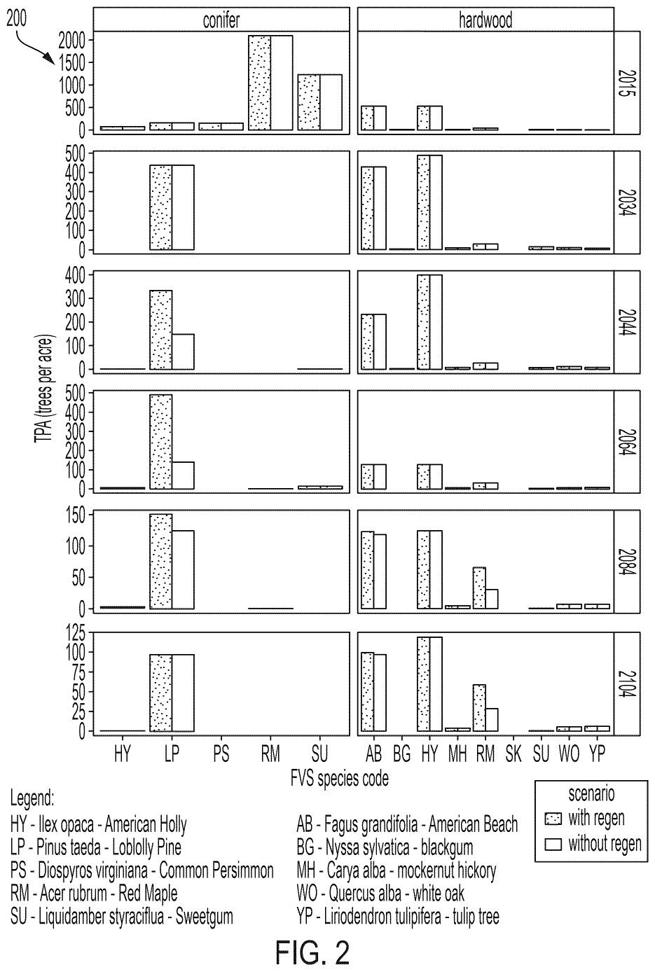

FIG. 2 illustrates the effect on predicted forest growth over time from using the method disclosed above. In particular, FIG. 2 shows a related set of bar graphs 200 that show an estimated number of trees per acre (TPA) for each of several different tree species at each of several points in time. Each bar graph shows TPA with and without the effect of the regeneration models. The effect may be seen more clearly with respect to particular tree species. For example, estimates of TPA of the Loblolly Pine that include the regeneration models show a great number of trees per acre during intermediate years (e.g., 2044, 2064, 2084) than estimates that do not include the regeneration models. The difference may be subtle, but measurable. Over time, however, the estimates may converge (e.g., as seen in the estimate for 2104). One explanation for convergence is that, given enough time, forests will typically approach a limit known as the “carrying capacity” of the location they are growing in. Until that limit is reached, the dynamics (e.g., rate of growth) and composition of the forest (e.g., species distribution) have important implications for how the forest stand may be managed.

Of note, FIG. 2 shows data for a forest plot that has a typical silviculture applied to it, including a “thinning” regime. In the case of a conifer stand, the thinning regime may include a shelterwood harvest (i.e., a series of partial cuts to regenerate a forest stand, including (i) a preparatory cut in which the smallest trees are removed to improve sunlight conditions for new growth (ii) an establishment cut in which a portion of the canopy is removed while retaining the largest, most vigorous trees, and (iii) a final harvest in which the remaining canopy trees are removed when the new growth reaches a certain height). That is, a goal of shelterwood harvest is to increase sunlight to the forest floor while maintaining a seed source in the overstory to encourage new tree seedlings. In the case of a hardwood plot, the thinning may be based on free age, size, or other aspects (e.g., trees that are small, forked, or diseased). Thus, the estimated trees per acre may vary according to the applied silviculture as well as regeneration.

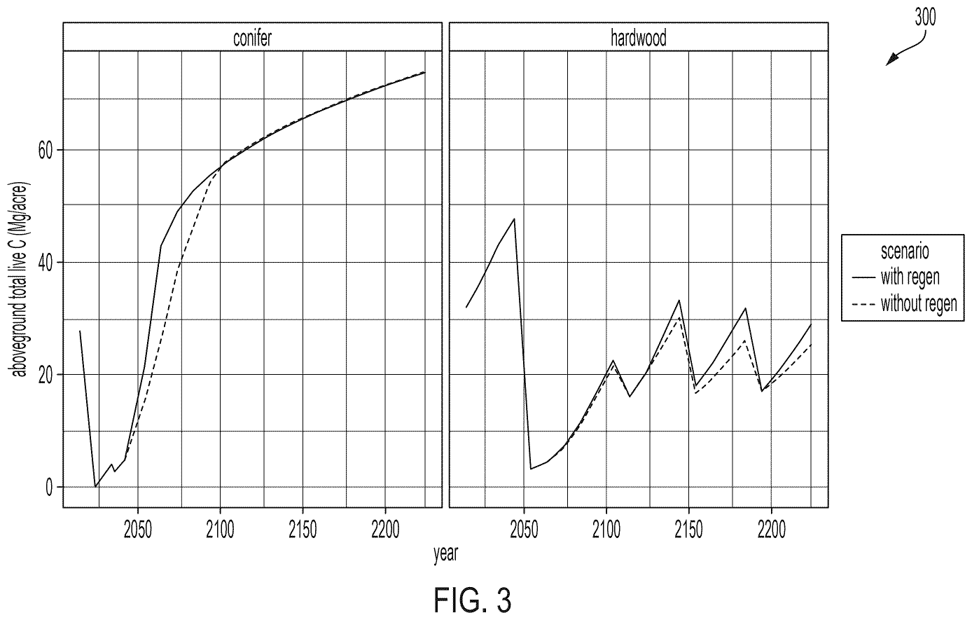

FIG. 3 illustrates the effect on predicted forest growth over time from using the disclosed method. In particular, FIG. 3 shows a graph 300 showing an estimated amount of aggregate above-ground carbon in the conifer and hardwood trees. A solid line shows the estimate including the regeneration models, and a dashed line shows the estimate without the regeneration models. As in the case of FIG. 2, the effect may be seen more clearly with respect to conifers and during intermediate years (e.g., between about 2040 and 2100). For hardwoods, the estimates tend to diverge between thinning events.

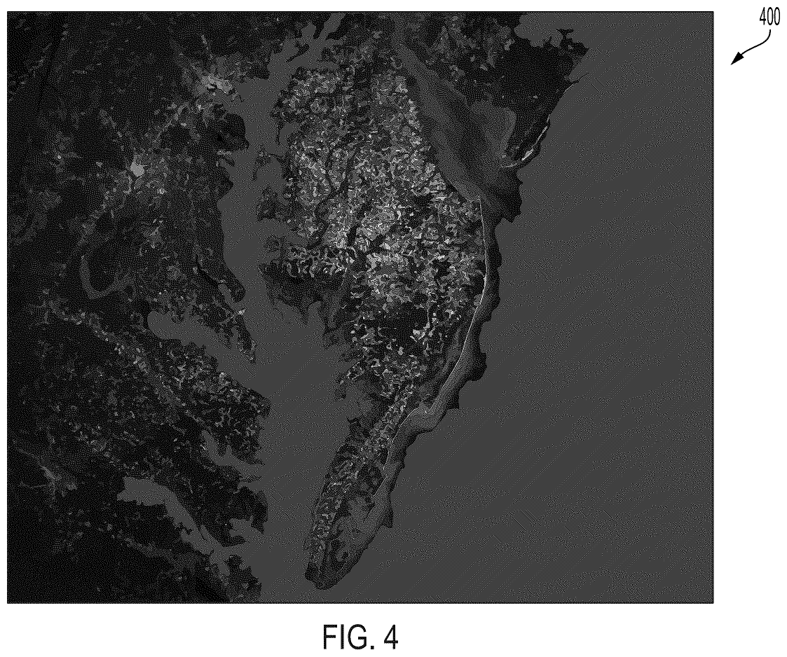

The machine-learning models may be trained on empirical forest data from a variety of reliable sources. FIG. 4 shows example satellite sensor data 400 at a point in time. Here, the data depicts a portion of the Earth's surface. The depicted portion may include land within an ecoregion, i.e., a relatively large region (e.g., up to the continental scale) containing substantially a single ecosystem or a small number of ecosystems having substantially similar phenological characteristics. The ecoregion may include forested and unforested land. The example sensor data may include measurements of light reflected from the ecoregion within multiple separate frequency bands. Typically, governmental agencies that collect, warehouse, and serve satellite data group this data into categories depending on the level of processing associated with the sensor data. The lowest level data products are the raw data collected by the sensors. The next level of data usually involves calibrating and correcting raw data to better reflect the surface reflectance after removing atmospheric effects. Combinations of separate corrected measurements into one or more index values per pixel, e.g., according to a standard index, such as the normalized difference vegetation index (NDVI) could be considered a 3rd category of data. In some examples, the portion of the Earth's surface represented by individual pixels of the sensor data is defined by the spatial resolution of the sensor. Each pixel may have an associated land-use classification, e.g., a classification applied by a government agency, such as the U.S. Geological Survey, based on expert assessment of the land and associated data. The land-use classification may distinguish forested lands from, e.g., developed land or from barren land. The land-use classification may further distinguish types of forested lands, e.g., deciduous, coniferous, mixed, etc. In some examples, a forest-cover classification is derived from the land-use classification. For example, all non-forest land-use classes may be summarized by a single class of “non-forest.”

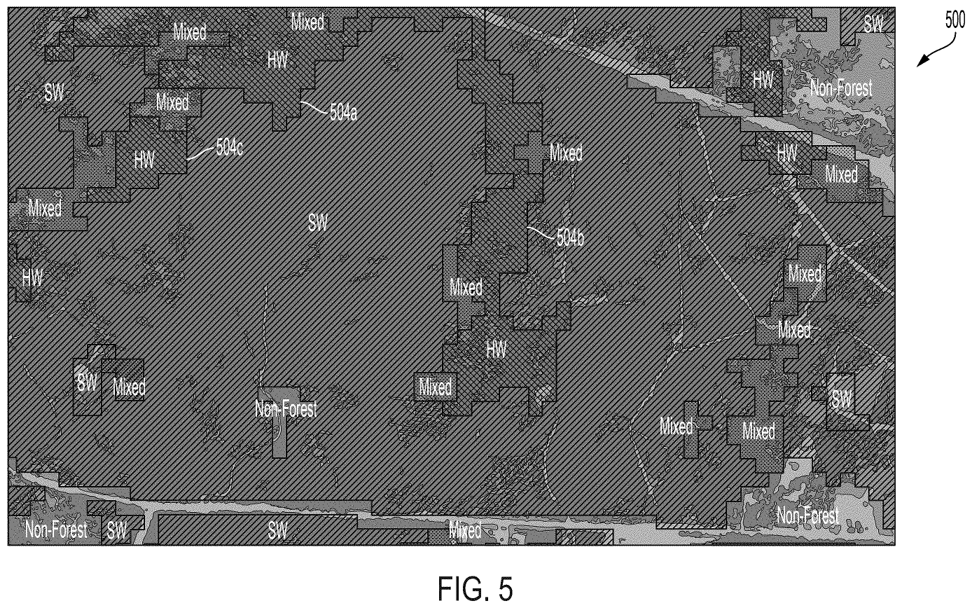

FIG. 5 shows example data 500 of forested subregions 504, 504a-c of an ecoregion. Each subregion 504 may be individually owned or owned by multiple landowners. Each subregion 504 may be enrolled in a program to earn carbon credits in return for maintaining the forest in the subregion 504. The program may include monitoring of the subregion 504 to assess adherence to forest maintenance obligations. For example, the program may continually monitor the subregions to detect changes to the forest cover. If a change is detected, the program may inform the subregion owner of the anomaly and ask for further assurances that the owner is maintaining the subregion 504 in accordance with the program.

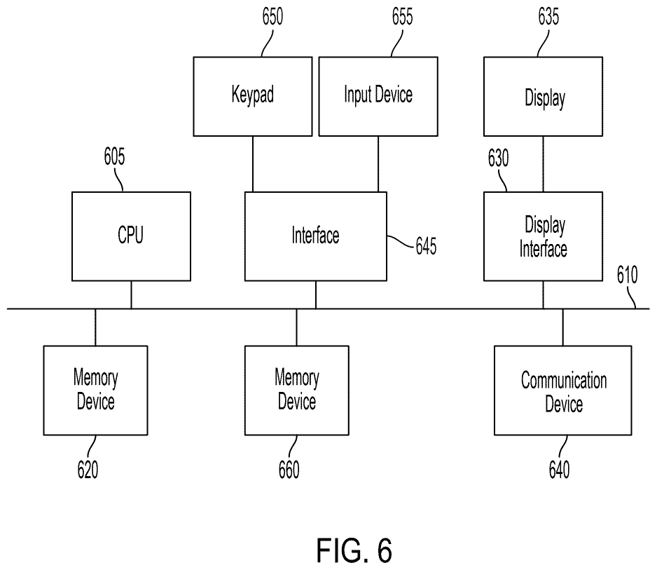

FIG. 6 illustrates example hardware that may be used to contain or implement program instructions. A bus 610 serves as the main information highway interconnecting the other illustrated components of the hardware. Processor 605 is a central processing device of the system, configured to perform calculations and logic operations required to execute programming instructions. As used in this document and in the claims, the terms “processor” and “processing device” may refer to a single processor 605 or any number of processors in a set of processors that collectively perform a set of operations, such as a central processing unit (CPU), a graphics processing unit (GPU), a remote server, or a combination of these. Read only memory (ROM), random access memory (RAM), flash memory, hard drives and other devices capable of storing electronic data constitute examples of memory devices 620. Read only memory (ROM) and random-access memory (RAM) constitute examples of non-transitory computer-readable storage media 620, memory devices or data stores as such terms are used within this disclosure.

Program instructions, software or interactive modules for providing the interface and performing any querying or analysis associated with one or more data sets may be stored in the memory device 620. Optionally, the program instructions may be stored on a tangible, non-transitory computer-readable medium such as a compact disk, a digital disk, flash memory, a memory card, a universal serial bus (USB) drive, an optical disc storage medium and/or other recording medium.

An optional display interface 630 may permit information from the bus 610 to be displayed on the display 635 in audio, visual, graphic or alphanumeric format. Communication with external devices may occur using various communication ports 640. A communication port 640 may be attached to a communications network, such as the Internet or an intranet.

An optional display interface 630 may permit information from the bus 610 to be displayed on a display device 635 in visual, graphic or alphanumeric format. An audio interface and audio output (such as a speaker) also may be provided. Communication with external devices may occur using various communication devices 640 such as a wireless antenna, a radio frequency identification (RFID) tag and/or short-range or near-field communication transceiver, each of which may optionally communicatively connect with other components of the device via one or more communication system. The communication device(s) 640 may include a transmitter, transceiver, or other device that is configured to be communicatively connected to a communications network, such as the Internet, a Wi-Fi or local area network or a cellular telephone data network, or to make a direct communication connection with one or more nearby devices, such as a Bluetooth transmitter or infrared light emitter.

The hardware may also include a user interface sensor 645 that allows for receipt of data from a keyboard or keypad 650 or other input devices 655 such as, a joystick, a touchscreen, a touch pad, a remote control, a pointing device and/or microphone. Digital image frames also may be received from a camera 660 that can capture video and/or still images.

In this document, an “electronic device” or a “computing device” refers to a device that includes a processor and memory. Each device may have its own processor and/or memory, or the processor and/or memory may be shared with other devices as in a virtual machine or container arrangement. The memory will contain or receive programming instructions that, when executed by the processor, cause the electronic device to perform one or more operations according to the programming instructions.

The terms “memory,” “memory device,” “computer-readable medium,” “data store,” “data storage facility” and the like each refer to a non-transitory device on which computer-readable data, programming instructions or both are stored. Except where specifically stated otherwise, the terms “memory,” “memory device,” “computer-readable medium,” “data store,” “data storage facility” and the like are intended to include single device embodiments, embodiments in which multiple memory devices together or collectively store a set of data or instructions, as well as individual sectors within such devices. A computer program product is a memory device with programming instructions stored on it.

The terms “processor” and “processing device” refer to a hardware component of an electronic device that is configured to execute programming instructions, such as a microprocessor or other logical circuit. A processor and memory may be elements of a microcontroller, custom configurable integrated circuit, programmable system-on-a-chip, or other electronic device that can be programmed to perform various functions. Except where specifically stated otherwise, the singular term “processor” or “processing device” is intended to include both single-processing device embodiments and embodiments in which multiple processing devices together or collectively perform a process.

A “machine learning model” or a “model” refers to a set of algorithmic routines and parameters that can predict an output(s) of a real-world process (e.g., identification or classification of an object) based on a set of input features, without being explicitly programmed. A structure of the software routines (e.g., number of subroutines and relation between them) and/or the values of the parameters can be determined in a training process, which can use actual results of the real-world process that is being modeled. Such systems or models are understood to be necessarily rooted in computer technology, and in fact, cannot be implemented or even exist in the absence of computing technology. While machine learning systems utilize various types of statistical analyses, machine learning systems are distinguished from statistical analyses by virtue of the ability to learn without explicit programming and being rooted in computer technology. A machine learning model may be trained on a sample dataset (referred to as “training data”).

In this document, the term “wireless communication” refers to a communication protocol in which at least a portion of the communication path between a source and destination involves transmission of a signal through the air and not via a physical conductor, as in that of a Wi-Fi network, a Bluetooth connection, or communications via another short-range or near-field communication protocol. However, the term “wireless communication” does not necessarily require that the entire communication path be wireless, as part of the communication path also may include a physical conductors positioned before a transmitter or after a receiver that facilitate communication across a wireless position of the path.

While the invention has been described with specific embodiments, other alternatives, modifications and variations will be apparent to those skilled in the art. Accordingly, it will be intended to include all such alternatives, modifications, and variations within the spirit and scope of the appended claims.

1. A method of estimating forest regeneration, the method comprising:
accessing a first model trained to predict a proportion of saplings in a forest after a disturbance;
accessing a second model trained to predict a distribution of sapling species in a forest after a disturbance;
iteratively executing a forest growth and yield model to simulate growth of a stand of a forest;
for at least one iteration:
retrieving, from the forest growth and yield model, information about the stand;
applying the first model to the retrieved stand information to estimate the proportion of saplings in the stand;
applying the second model to the retrieved stand information to estimate the distribution of sapling species in the stand; and
adjusting the stand information of the forest growth and yield model based on the estimated proportion of saplings and/or the estimated distribution of sapling species; and
receiving, from the forest growth and yield model, a final report on the stand.

2. The method of claim 1, further comprising training the first model to predict the proportion of saplings in a forest after a disturbance, the proportion of saplings comprising a ratio of a number of saplings to a total trees per acre (TPA) in the stand.

3. The method of claim 2, wherein training the first model comprises training a Random Forest (RF) model.

4. The method of claim 3, wherein training the RF model comprises:
accessing information including sapling counts by species for each of a plurality of plots of a forest; and
training the RF model on at least a portion of the accessed information.

5. The method of claim 4, wherein training the RF model further comprises preprocessing the accessed information to exclude plots having less than a threshold number of saplings before training the RF model.

6. The method of claim 1, further comprising training the second model to predict the distribution of sapling species in a forest after a disturbance.

7. The method of claim 6, wherein training the second model comprises training an Artificial Neural Network (ANN) model.

8. The method of claim 6, wherein training the ANN model comprises training a deep neural network (DNN) having at least one layer that includes a softmax activation function.

9. The method of claim 6, wherein training the ANN model comprises training a DNN network having at least inner layers that each includes a sigmoid activation function.

10. The method of claim 1, iteratively executing the forest growth and yield model to simulate growth of the stand of a forest comprises executing the forest growth and yield model to iterate over a plurality of time periods.

11. The method of claim 1, further comprising, after applying the second model to the retrieved stand information, applying one or more constraints or adjustments to an output of the first model and/or the second model.

12. The method of claim 11, wherein applying the one or more constraints or adjustments comprises reducing the estimated number of saplings based on a proportion of a basal area of a sapling species in the overstory.

13. The method of claim 1, further comprising, after completing all iterations, outputting the final report regarding the stand.

14. The method of claim 1, further comprising, before applying the first model to the retrieved stand information, validating the first model based on a k-fold-cross-validation.
